(19) United States
(12) Patent Application Publication
(10) Pub. No.: US 2006/0110842 A1
(43) Pub. Date: May 25, 2006

(54) Method and apparatus for preventing metal/silicon spiking in MEMS devices

(76) Inventors: Yuh-Hwa Chang, Shulin City (TW); Fei-Yun Chen, Hinchu (TW); Jiann-Tyng Tzeng, Hsinchu (TW); Cheng-Yu Chu, Qsonglin Shiang (TW); Chun-Kai Peng, Hsinchu City (TW); Chih-Chieh Yeh, Hsinchu City (TW); Chih-Heng Po, Zaociao Township (TW); Dah-Chuen Ho, Taichung City (TW)

Correspondence Address: DUANE MORRIS, LLP;IP DEPARTMENT, 30 SOUTH 17TH STREET, PHILADELPHIA, PA, 19103-4196, US

(21) Appl. No.: 10/996,234

(22) Filed: Nov. 23, 2004

(51) Int. Cl. H01L 21/00; H01L 31/0203

(52) U.S. Cl. 438/51; 257/433

(57) ABSTRACT

The disclosure relates to a method and apparatus for preventing extrusion or spiking of a metal atom from a metallization layer to other layers of a silicon wafer. In one embodiment, the method includes forming a silicon-on-ship device with a MEMS component on the substrate. The MEMS component may include one or more metal or metallic alloys. To prevent spiking from the MEMS component, the sides thereof can be coated with one ore more spacer or barrier layers. In one embodiment, oxygen plasma and thermal oxidation methods are used to deposit spacers. In another embodiment, an oxide layer is deposited over the wafer, covering the substrate and the MEMS component. Selective etching or anisotropic etching can be used to remove the oxide layer from certain regions of the MEMS and the substrate while covering the sidewalls. An amorphous silicon layer can then be deposited to cover the MEMS device.

### BACKGROUND

A Micro-Electro-Mechanical (“MEMS”) device defines the integration of electromechanical elements on a common silicon substrate through micro-fabrication technology. The electrical elements such as complementary metal oxide semiconductor (“CMOS”) or bipolar devices are fabricated on an underlying silicon substrate using integrated circuit (“IC”) processes while the micro-mechanical components are fabricated by micro-machining processes that selectively etch away regions of the silicon substrate. The machining of the mechanical devices on the same silicon substrate results in a complete system-on-a-chip technology.

The process steps and sequences needed for MEMS can present possible vulnerabilities for the semiconductor device components of MEMS. Such problems do not arise in traditional semiconductor fabrications. For example, amorphous silicon is used for the sacrificial layer in MEMS devices. The sacrificial amorphous silicon material may directly interface with material such as aluminum which is used for the mechanical or conductive components of MEMS.

When the structure is subjected to heat treatment processes, extrusion occurs along the sidewalls of the metal line structure. Extrusion (or spiking) is the migration of metal atoms, molecules or ions into an adjacent layer such as silicon. Extrusion is a defect and can have adverse affects on the underlying device. Thus, there is a need for a method and apparatus configured to prevent spiking or extrusion of aluminum into adjacent silicon regions.

### SUMMARY OF THE DISCLOSURE

In one embodiment, the disclosure relates to a method for eliminating extrusion from a metallic atom of a MEMS device to a silicon layer of an IC wafer by providing a substrate having a MEMS structure thereon. The MEMS structure may include a metallization layer interposed between a first barrier layer and a second barrier layer. The MEMS structure may also include at least two exposed sidewalls. The method according to one embodiment of the disclosure includes depositing an oxide layer over the spacer structure to form a spacer covering each of the two sidewalls; selectively etching to remove the oxide layer while not affecting the spacers; forming a silicon layer to substantially cover the spacer structure, the metallization layer being separated from the silicon layer at each side by at least one of the spacer or the barrier layer.

In another embodiment, the disclosure relates to a method for preventing extrusion of metal along the contact walls of a MEMS device formed on a silicon wafer. The method includes providing a substrate having the MEMS structure thereon, the MEMS structure defined by a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls; forming one or more spacer layers to conceal each of the sidewalls; and depositing a silicon layer to substantially cover the spacer structure, the metallization layer being separated from the silicon layer at each side by at least one of the spacers or the barrier layers.

In still another embodiment, the disclosure relates to a Micro-Electro-Mechanical device having electrical components formed on an integrated circuit wafer. A method for eliminating extrusion of metallic atoms of the MEMS device onto a silicon layer of the IC wafer includes providing a substrate having the MEMS structure thereon, the MEMS structure defined by a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls; using oxygen plasma to form a plurality of spacers to cover the at least two side walls of the MEMS structure; growing amorphous silicon over the substrate to substantially cover the spacer structure, the metallization layer being separated from the amorphous silicon layer by at least one of the spacers or the barrier layers.

In yet another embodiment, the disclosure relates to preventing spiking between metallic portions of a MEMS device and an IC wafer by providing a substrate having the MEMS structure thereon, the MEMS structure defined by a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls; using thermal oxidation to form a plurality of spacers to cover the at least two side walls of the MEMS structure; growing amorphous silicon over the substrate to substantially cover the spacer structure, the metallization layer being separated from the amorphous silicon layer by at least one of the spacers or the barrier layers.

### BRIEF DESCRIPTION OF THE DRAWINGS

FIGS. 1A-D illustrate a method for preventing extrusion according to one embodiment of the disclosure;

FIGS. 2A-C illustrate a method for preventing extrusion by using oxygen plasma coating; and

FIGS. 3A-C illustrate a method for preventing extrusion by using thermal oxidation to form a spacer structure.

### DETAILED DESCRIPTION OF THE DISCLOSURE

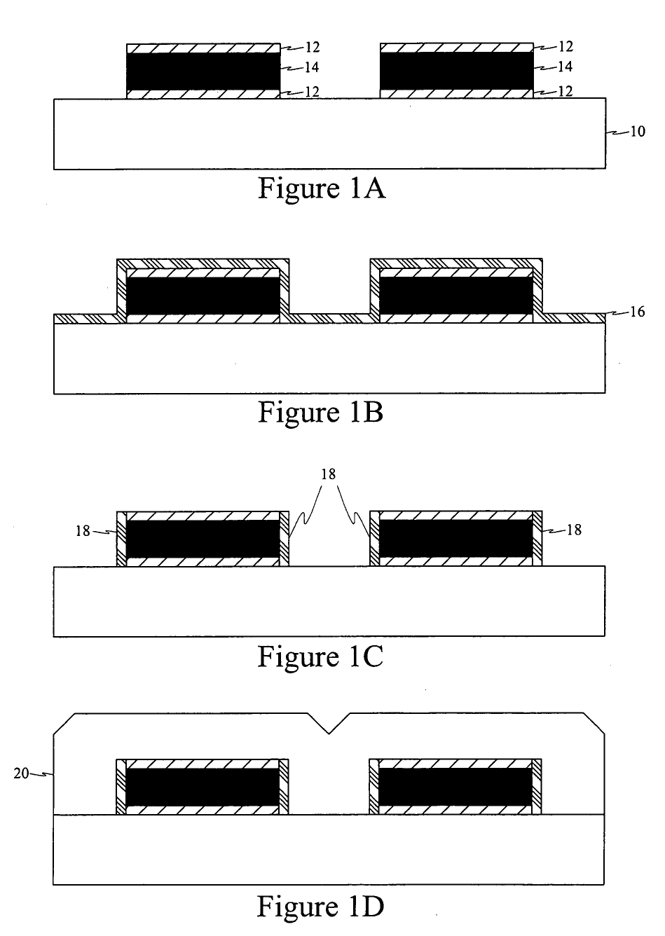

FIG. 1 schematically illustrates a method for preventing extrusion according to one embodiment of the disclosure. Referring to FIG. 1A, substrate 10 is provided having deposited thereon barrier layers 12 and the conductive layers 14. Substrate 10 can include conventional semiconductor material such as silicon. Semiconductor substrate 10 may have a plurality of MOS transistors (not shown) incorporated therein. The barrier layer can be formed from titanium nitride (TiN), titanium (Ti), tungsten nitride (WN), an alloy of titanium and tungsten (Ti/W), silicon dioxide or silicon nitride. The barrier layer serves to prevent spiking (or extrusion) between the conductive layers (interchangeably, the metallization layers) 14 and substrate 10. In one embodiment, the barrier layer has a thickness of about 200-500 Angstroms. The barrier layers can be deposited using conventional deposition techniques including CVD or PVD.

The metallization layer 14 can be formed from aluminum, copper and alloys thereof. In one embodiment, the metallization layer comprises an alloy of AlSiCu. The metallization layer may also comprise one or more MEMS device fabricated by micro-machining processes and selectively positioned on substrate 10. The exemplary embodiment shown in FIG. 1A can be prepared according to any conventional deposition techniques.

In the embodiment of FIG. 1A, metallic layer 14 is interposed between barrier layers 14. A combination of metallic layer 14 and barrier layers 12 can constitute a MEMS component or a MEMS device. As seen in FIG. 1A, the sides of metallic layer 14 is exposed and subject to extrusion if contacted with a silicon layer. As discussed, the exposed sidewalls can cause spiking between metallization layers and the subsequently-deposited silicon layer.

Referring now to FIG. 1B, spacer barrier layer 16 is deposited over the structure shown in FIG. 1A. The deposition technique can include conventional methods including sputtering, chemical vapor deposition (CVD) or plasma-enhanced chemical vapor deposition (PECVD). The spacer barrier layer 16 may include, among others, silicon oxide, silicon nitride (SiN), titanium nitride (TiN) and titanium.

In FIG. 1C, the spacer barrier layer 16 is etched back to expose substrate 10 and barrier layers 12. Among others, anisotropic etching (or dry etching) can be used for this step. A mask or a photo-resist layer (not shown) can be deposited to cover the sidewalls prior to etching. Spacers 18 can effectively prevent extrusion or spiking from the metallization layers 14.

Finally, in step 1D silicon layer 20 can be deposited to substantially cover substrate 10, sidewalls 18 and barrier layers 12. The barrier layers prevent extrusion of metal atoms from the top surface of metallization layers 14 while spacers 18 protect extrusion from the sidewalls. While FIG. 1D shows a two-dimensional representation of an exemplary embodiment, it can be readily seen that the principles disclosed herein can be extended to cover sides of a three-dimensional device without departing from the spirit of the disclosure.

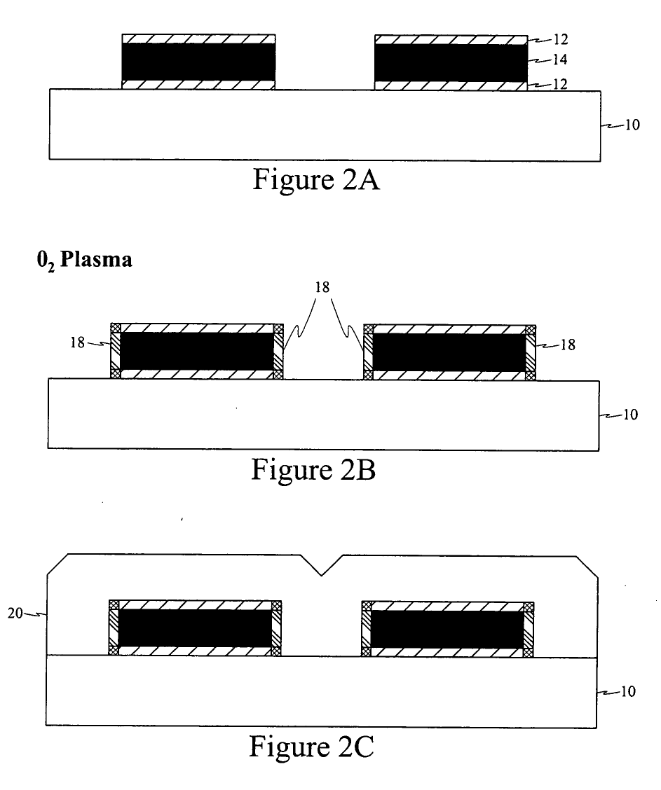

FIGS. 2A-C schematically illustrate a method for preventing extrusion by using oxygen plasma coating in accordance with another embodiment of the disclosure. FIG. 2A shows an embodiment having a MEMS device similar to that shown in FIG. 1A. It should be noted that the representation in FIG. 1A is exemplary and although two MEMS devices are shown on a wafer, the disclosure is not limited thereto and may include a number of MEMS devices.

According to one embodiment of the disclosure, spacers 18 are formed on the sides exposed of the MEMS device through oxygen plasma. The oxygen plasma step can be performed in situ to form a barrier layer between the MEMS device and the subsequently-deposited semiconductor wafer. The barrier can be an aluminum/oxide barrier layer. Thereafter, a silicon layer can be deposited to cover the entire structure including the MEMS device and the wafer. In one embodiment, the silicon layer is an amourphous silicon layer. In another embodiment, the amorphous silicon layer is grown on the substrate using a seed layer (not shown).

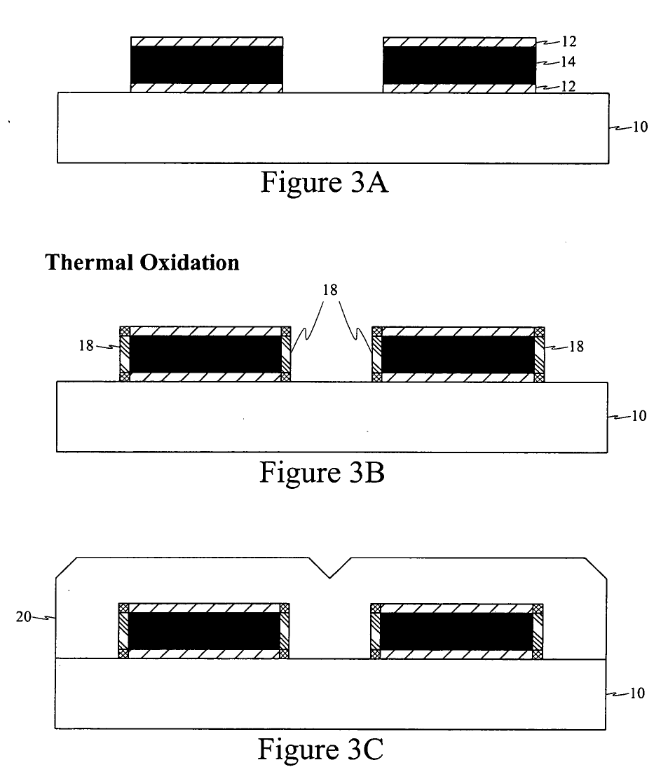

FIGS. 3A-C illustrate a method for preventing extrusion by using thermal oxidation to form a spacer structure. Specifically, FIG. 3A shows an embodiment having a MEMS device similar to that shown in FIG. 1A. The MEMS device can be any structure having a metallization layer 14 such that the metallization layer includes one ore more of Al, Cu or other similar metals. Referring to FIG. 3A, substrate 10 includes barrier layers 12 and metallization layers 14. Metallization layer 14 is interposed between the barrier layers. One barrier layer (the bottom layer) interfaces the substrate and the metallization layer 14 white the top barrier layer coves a surface of metallization layer 14. According to one embodiment of the disclosure, (see FIG. 3B) spacers 18 are deposited on the exposed sides of the metallization layer 14. The spacers can be deposited using, among others, thermal oxidation. There are at least three ways to form oxide spacer. The first method is thermal oxidation. Here, a metal oxide is formed in furnace with oxygen environment and at temperature of about 300-500° C. The oxidation time is about 20-120 minutes. In one embodiment, the metal oxide can be formed at 350° C. for about 30 minutes. The second method to form the spacers is to deposit a PECVD-oxide layer over metallization layer 14 and then etch back the oxide layer. The thickness of the PECVD-oxide layer can be in the range of about 400-1000 Å. In one of the embodiment, the thickness can be 800 Å. The conditions of depositing and etching-back is conventional. The third method is use of oxygen plasma to form metal oxide spacer in the side wall of metal layer. The temperature can be in the range of about 150-200° C.

Referring to FIG. 3C, a layer of amorphous silicon is deposited on the entire structure. As can be seen, the metallization layers 14 are separated from the amorphous silicon layer through barrier layers 12 and spacers 18.

While the principles of the disclosure have been described in relation to specific embodiments illustrated herein, it should be noted that the disclosure is not limited thereto. Accordingly, the principles of the disclosure include all permutations and variations to the embodiments presented herein and any modification thereof.

1. A method for preventing extrusion of metal along the contact walls of a MEMS device formed on a silicon substrate, the method comprising:
providing a substrate having the MEMS structure thereon, the MEMS structure having a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls;
depositing a dielectric layer over the MEMS structure to cover each of the at least two sidewalls;
selectively etching the dielectric layer to form a spacer structure in the two sidewalls; and
forming a dielectric layer covering the MEMS structure and at least a portion of the substrate.

2. The method of claim 1, wherein at least one of the first or the second barrier layer further comprises one or more of titanium nitride, titanium, tungsten nitride, an alloy of titanium and tungsten, silicon dioxide or silicon nitride.

3. The method of claim 1, wherein the dielectric layer further comprises silicon oxide or silicon nitride.

4. The method of claim 1, wherein the step of depositing a dielectric layer includes plasma enhanced chemical vapor deposition.

5. The method of claim 1, wherein the step of depositing a dielectric layer includes plasma sputtering.

6. The method of claim 1, wherein the dielectric layer is a silicon layer to substantially cover the spacer structure.

7. The method of claim 1, wherein the silicon dielectric layer is an amorphous silicon layer.

8. The method of claim 1, wherein the step of selectively etching the oxide layer further comprises anisotropic etching.

9. The method of claim 1, wherein the MEMS structure contains at least one of Al, Si and Cu.

10. A semiconductor wafer having a MEMS device thereon prepared according to the method of claim 1.

11. A method for preventing extrusion of metal along the contact walls of a MEMS device formed on a silicon substrate comprising:
providing a substrate having the MEMS structure thereon, the MEMS structure defined by a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls;
forming one or more spacer layers to conceal each of the sidewalls; and
depositing a silicon layer to substantially cover the spacer structure.

12. The method of claim 11, wherein the metallization layer is substantially separated from the silicon layer at each side by at least one of the spacers.

13. The method of claim 11, wherein the silicon layer is an amorphous silicon grown by plasma-enhanced chemical vapor deposition.

14. The method of claim 11, wherein the step of forming one or more spacer layer further comprises using oxygen plasma for forming the spacers.

15. The method of claim 11, wherein the step of forming one or more spacer layer further comprises using thermal oxidation to form the spacers.

16. The method of claim 11, wherein at least one of the first or the second barrier layer further comprises further comprises one or more of titanium nitride, titanium, tungsten nitride, an alloy of titanium and tungsten, silicon dioxide or silicon nitride.

17. A method for preventing extrusion of metal along the contact walls of a MEMS device formed on a silicon substrate, the method comprising:
providing a substrate having the MEMS structure thereon, the MEMS structure defined by a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls;
using oxygen plasma to form a plurality of spacers to cover the at least two side walls of the MEMS structure; and
growing amorphous silicon over the substrate to substantially cover the spacer structure.

18. The method of claim 17, wherein the step of using oxygen plasma is performed in the temperature of about 150-200° C.

19. A silicon-on-chip device having a MEMS component fabricated according to the process of claim 17.

20. The method of claim 17, wherein the metallization layer further comprises an element selected from the group consisting of Al, Cu and Si.

21. The method of claim 17, wherein the oxide layer is selected from the group consisting of silicon oxide, silicon nitride, titanium nitride and titanium.

22. A method for preventing extrusion of metal along the contact walls of a MEMS device formed on a silicon substrate, the method comprising:
providing a substrate having the MEMS structure thereon, the MEMS structure defined by a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls;
using thermal oxidation to form a plurality of spacers to cover the at least two side walls of the MEMS structure;
growing amorphous silicon over the substrate to substantially cover the spacer structure.

23. The method of claim 22, wherein the metallization layer further comprises an element selected from the group consisting of Al, Cu and Si.

24. A MEMS device formed on a silicon substrate comprising:
a substrate having the MEMS structure thereon, the MEMS structure defined by a metallization layer interposed between a first barrier layer and a second barrier layer, the first barrier layer interfacing the substrate and a bottom surface of the metallization layer and the second barrier layer interfacing a top surface of the metallization layer, the MEMS structure having a top surface and at least two sidewalls;
one or more spacer layers substantially concealing each of the sidewalls; and
a silicon layer to substantially cover the spacer structure.

25. The device of claim 24, wherein the spacer layer is oxide spacer.
